(19) United States
(12) Patent Application Publication
(10) Pub. No.: US 2020/0299146 A1
(43) Pub. Date: Sep. 24, 2020

(54) METHODS AND SYSTEMS FOR HIGH TEMPERATURE SUPERCONDUCTORS

(71) Applicant: Eastern Plus, LLC, Cleveland, OH (US)

(72) Inventors: Dong Zhao, Santa Clara, CA (US); George Jin Zhao, Cleveland, OH (US)

(21) Appl. No.: 16/083,804

(22) PCT Filed: Jan. 26, 2017
(86) PCT No.: PCT/US2017/015120

§ 371 Date: Sep. 10, 2018

Related U.S. Application Data
(63) Continuation-in-part of application No. 15/077,683, filed on Mar. 22, 2016, now abandoned.

(51) Int. Cl. C01F 15/00; C01B 6/02; H01F 6/00; H01F 1/00; H01L 39/12

(52) U.S. Cl. CPC C01F 15/00; C01B 6/02; H01F 6/00; C01P 2002/77; H01L 39/125; C01P 2006/40; C01P 2006/42; H01F 1/0018

(57) ABSTRACT

The present disclosure provides a method for using a group of actinide and lanthanide (rare earth) metal compounds as well as early transition metal compounds that have the electric superconducting property at 151 K or higher that have the potential to reach a superconducting transition (critical) temperature (Tc) of room temperature (298 K) or even higher.

### CROSS-REFERENCE TO RELATED APPLICATIONS

This application is a continuation-in-part of U.S. application Ser. No. 15/077,683, filed on Mar. 22, 2016. This prior application is incorporated herein by reference for all purposes.

### FIELD

This application relates to the field of superconductors, in particular high temperature superconductors.

### BACKGROUND

Since the first discovery of the superconductive phenomenon of mercury at its transition (critical) temperature (Tc) of 4.2 K in 1911, the work of exploring higher and higher Tc superconductors progressed slowly for about 75 years. (See FIG. 1.) This slow progress was interjected by the major revolutionary discovery of superconductivity on certain lanthanum based cuprate Perovskite ceramics, the so called type II superconducting materials, in 1986. The detail exploratory work for this study can be found in Bednorz, J. G. and Muller, K. A., “Possible High Tc Superconductivity in the Ba—La—Cu—O System”, Z. Phys. B 64, 189 (1986), which is incorporated herein by reference. This finding led the Tc to successfully outreach the milestone of 77 K, i.e., the boiling temperature of liquid nitrogen, within a year as reported in Wu, M. K. et al., “Superconductivity at 93 K in a New Mixed-Phase Y—Ba—Cu—O Compound system at Ambient Pressure”, Phys. Rev. Lett. 58 (9) 908 (1987), which is incorporated herein by reference. The further enhancement of Tc on the cuprate Perovskite ceramics via cation and/or anion modifications reached in the vicinity of 138 K in 1995, which is the widely accepted highest world record of Tc hitherto excluding the Tc that was obtained through applying external energy to the compounds, such as radiation, electric field or extra pressure. A typical publication of this work is Dai, P., et al., “Synthesis and neutron powder diffraction study of the superconductor HgBa₂Ca₂Cu₃O_{8+δ} by Tl substitution”, Physica C243, 201 (1995), which is incorporated herein by reference.

It has been 30 years after the discovery of the type II superconductivity. Great effort on preparing higher and higher Tc superconductive materials has been made in the hope of exceeding the other two major milestones, viz., the melting point of water (273 K) and the room temperature (298 K). A few of the relevant works are listed here: Kawashima, Y., “Possible room temperature superconductivity in conductors obtained by bringing alkanes into contact with a graphite surface”, AIP Adv. 3, 052132 (2013); U.S. Pat. No. 5,126,319; U.S. Patent Application Publication, 2002/0006875 A1; and U.S. Patent Application Publication, 2012/0035057 A1, each of which is incorporated herein by reference.

The studies on certain cuprate Perovskites via an external optic stimulation showed possible room temperature superconductivity, but the results will need to be reconfirmed by different experiments while the reported metastable superconducting state existed too short in a span of several picoseconds to be used in any application. Theoretically speaking, this super short life time of superconducting state would make other experiments to confirm its existence extremely difficult. More information about this optical radiation induced high temperature superconductivity are as follows: Mankowsky, R., et al., “Nonlinear lattice dynamics as a basis for enhanced superconductivity in YBa₂Cu₃O_{6.5}”, Nature 516, 71-73 (2014), Hu, W., et al., “Optically enhanced coherent transport in YBa₂Cu₃O_{6.5} by ultrafast redistribution of interlayer coupling”, Nature Mater. 13, 705-711 (2014), Kaiser, S., et al., “Optically induced coherent transport far above Tc in underdoped YBa₂Cu₃O_{6+δ}”, Phys. Rev. B 89, 184516 (2014) and Fausti, D., et al., “Light-Induced Superconductivity in a Stripe-Ordered Cuprate”, Science 331, 189-191 (2011), each of which is incorporated herein by reference.

It is of great importance to have a stable superconducting material whose Tc can surpass one or both of the hereinbefore 273 K and 298 K milestones. Technically speaking, the even stricter requirements than the abovementioned two temperature marks of 273 K and 298 K for low power application need the Tc of superconductor to top 350 K while Tc for high power application should outpace 450 K as delineated in Mourachkine, A., “Room-Temperature Superconductivity”, Cambridge International Science Publishing (2004), which is incorporated herein by reference.

### SUMMARY

The present disclosure provides a method for using a group of metal compounds of actinide and lanthanide (rare earth) series along with several transition metal elements that have the electric superconducting property at 151 K or higher, and have the potential to reach a superconducting transition (critical) temperature (Tc) of room temperature (298 K) or even higher.

Among the compounds composed according to the formula of MXₙ, disclosed herein, several of them were made in the past at various or unknown levels of purity, but their superconducting property has not been realized hitherto. A typical publication of the syntheses of thorium compounds is Clark, R. J. and Corbett, J. D., “Preparation of Metallic Thorium Diiodide”, Inorg. Chem. 2, 460 (1963), which is incorporated herein by reference, and the references therein can be tracked back to 1949 for the thorium compounds. Consequently, the disclosure herein focuses on repurposing these compounds, for the first time, in a method for high temperature superconducting, and devices or systems or other applications incorporating the high temperature superconducting materials.

### BRIEF DESCRIPTION OF THE DRAWINGS

FIG. 1 is a graph showing the history of superconductor development by plotting the advances of the superconducting transition (critical) temperature, Tc, in Kelvin (K) against the time in year.

FIG. 2A and FIG. 2B are three-dimensional diagrams showing two geometries for the [ThI₆] structural units: (A) Trigonal-antiprismatic (anti-Pris), and (B) Trigonal-prismatic (Pris). (Re-plotted according to Guggenberger, L. J. and Jacobson, R. A., “The Crystal Structure of Thorium Diiodide”, Inorg. Chem. 7, 2257 (1968), incorporated herein by reference.) FIG. 3 is a three-dimensional diagram showing the crystallographic unit cell of ThI₂ in a way that two geometries of the [ThI₆] units, i.e., anti-Pris and Pris, are stacked alternatively along the Z-axis. (Re-plotted according to Guggenberger, L. J. and Jacobson, R. A., “The Crystal Structure of Thorium Diiodide”, Inorg. Chem. 7, 2257 (1968), incorporated herein by reference. The “X”, “Y” and “Z” are used for the three abscissas to describe this structure same as used in this paper. The crystallographic convention based “a”, “b” and “c” axes are utilized in the other figures of this disclosure as “a-axis” defines the direction of X-axis, “b-axis” defines the direction of Y-axis and “c-axis” defines the direction of Z-axis.)

FIG. 4A-4D illustrate the orientations of the atomic geometries for each of the individual layers along the crystallographic c-axis of the ThI₂ hexagonal unit cell as shown in FIG. 3, where the cell positions (x, y, z) of thorium (Th) cations are (A) (⅔, ⅓, ¾); (B) (0, 0, ½); (C) (⅓, ⅔, ¼); and (D) (0, 0, 0).

FIG. 5A-5D are three-dimensional diagrams expanding on the connections of each layer in FIG. 4A-4D into four unit cells relatively and reveal the layered edge-sharing property of ThI₂. The connections in FIG. 5A and FIG. 5C are easy to see and only the side views are given while the extra top views in FIG. 5B and FIG. 5D are included for better visualizing the edge-sharing features of the 4-cell connections of the four [ThI₆] units.

FIG. 6 is a three-dimensional diagram showing a layout of a typical ThS (NaCl structure) and its layer feature on {111} planes is demonstrated, i.e., the layers of thorium cations (Th) and the layers of sulfur anions (S) are packed alternatively.

FIG. 7A is a three-dimensional diagram showing the crystal structure of ThS, where the six solid balls, representing sulfur anions (S), are replaced by hollow ones, also representing sulfurs, in order to depict the octahedral enclosure of sulfur anions (S) around one thorium cation (Th).

FIG. 7B is a three-dimensional diagram of an individual [ThS₆] octahedral structural unit stripped from FIG. 7A.

FIG. 8 is a three-dimensional diagram delineating the geometric arrangement of the ThS with the edge-sharing octahedral units of [ThS₆].

FIG. 9 is a diagram of an example computing device.

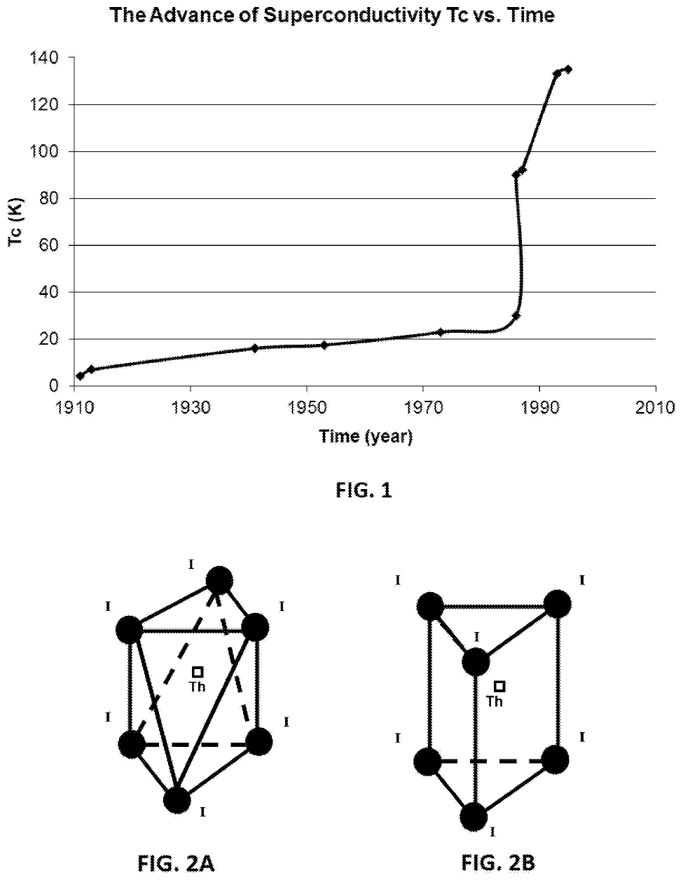

### DETAILED DESCRIPTION

In an embodiment disclosed herein, a “stable” material is used to conduct electricity or provide a magnetic field with no resistance at 151 K to room temperature (298 K) or even higher, such as, for example, 350 K to 450 K, or 273 K to 550 K (at atmospheric pressure). Here the term “stable” means the stable superconducting state, not necessarily chemically stable. In other words, the material can be chemically unstable, such as air or moisture sensitive, but must maintain its superconducting state stably without being helped through external energy, such as radiation, electric field or extra pressure, as long as the temperature is below its Tc at atmospheric pressure. The optical induced high temperature superconductivity on YBa₂Cu₃O_{6.5} was reported in Mankowsky, R., et al., “Nonlinear lattice dynamics as a basis for enhanced superconductivity in YBa₂Cu₃O_{6.5}”, Nature 516, 71-73 (2014) and Hu, W., et al., “Optically enhanced coherent transport in YBa₂Cu₃O_{6.5} by ultrafast redistribution of interlayer coupling”, Nature Mater. 13, 705-711 (2014), both of which are incorporated herein by reference. The pressure enhanced superconductivity on HgBa₂Caₙ₋₁CuₙO_{2n+2+δ} (n=1, 2, 3) was studied in Hunter, B. A., “Pressure-induced structural changes in superconducting HgBa₂Caₙ₋₁CuₙO_{2n+2+δ} (n=1, 2, 3) compounds”, Physica C 221 1 (1994), which is herein incorporated by reference. The extremely high pressure generated superconductivity on hydrogen sulfide or sulfur hydride (H₂S) was presented in Li, Y., et al., “The metallization and superconductivity of dense hydrogen sulfide”, J. Chem. Phys. 140 (17) 174712 (2014) and Drozdov, A. P., et al., “Conventional superconductivity at 203 kelvin at high pressures in the sulfur hydride system”, Nature 525, 73 (2015), both of which are incorporated herein by reference.

The material in this disclosure may be provided in various electronic or magnetic articles of manufacture, allowing enhancements in energy efficiency and/or speed, creating high flux of magnetic field in an economic manner, or simplifying the system design by eliminating cryogenic components. The material may be provided in other applications employing the high temperature superconducting properties of the disclosed materials.

Generally speaking, the metal compounds or salts made from lanthanide series and transition metals in this disclosure have very low or no radioactivity, and thus, there is no need for concern about the harm from radioactivity.

In an embodiment, the metal compounds or salts from actinide series disclosed herein have some level of radioactivity, which made them an unlikely choice for research and for use in electronic devices. However, in embodiments disclosed herein, the thorium compounds or salts may be selected to have a low level of radioactivity because the half-life of isotope thorium-232 with natural abundance of 99.98% is over 14.05 billion years through the least penetrable α-decay process. This level is much less than those employed in consumer ionization smoke detectors, which contain an isotope americium-241 with half-life of only 432.6 years, also via an α-decay process. Accordingly, in an embodiment, the superconducting material may be selected to contain a metal with a half-life of 300 years to 15 billion years, such as 1,000 to 100 million years, or 10,000 to 1 million years, in each case the radioactivity of the metal is via the least penetrable α-decay process.

Here, 151 K is the temperature defined as the low end of the Tc for the superconductors of this disclosure because no stable superconductor reported hitherto has had a Tc reaching this mark at normal pressure (1 atm). In other words, the high temperature superconducting states for these materials or compounds neither require being obtained by adding energy to the them, through, but not limited to, external radiation, nor exist transiently for only a short period of time. Also, the high temperature superconducting states exist at atmosphere pressure, meaning they do not require applying additional external pressures.

The chemical formula or the compositions of the compounds can be written as MXₙ, where the M is at least one from the actinide elements, i.e., thorium (Th), protactinium (Pa), uranium (U), Neptunium (Np), plutonium (Pu), americium (Am), curium (Cm), berkelium (Bk), californium (Cf), and their isotopes; the X represents at least one element from fluorine (F), chlorine (Cl), bromine (Br), iodine (I), oxygen (O), sulfur (S), selenium (Se), tellurium (Te), nitrogen (N), phosphorus (P), arsenic (As), antimony (Sb), carbon (C), silicon (Si), germanium (Ge), boron (B) and their isotopes. In an embodiment, n is a value ranging from 0.05 to 20, such as 0.1 to 10, or 0.2 to 5.

Because of the chemical resemblance between groups of actinide and lanthanide (rare earth), the elements from the lanthanide group are also included in this invention and hence the M, hereinbefore, also encompasses lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu) and their isotopes.

Several transition metal compounds demonstrate similar electromagnetic properties of the actinide salts. The properties of these transition metal compounds are very sensitive to their chemical stoichiometry. For instance, TaC_{0.8} (n=0.8) and NbC_{0.8} (n=0.8) both exhibit coexistence of electric conductivity and diamagnetism at room temperature while their property of diamagnetism changes dramatically with slight change of the n values. This magnetic property of metal carbides was reviewed in Toth, L. E., “Transition Metal Carbides and Nitrides”, Academic Press Vol. 7, (1971), which is incorporated herein by reference. Therefore, these transition elements are assigned to the M for the above formula of MXₙ as the candidates to build the high Tc superconductors. These transition metals are, scandium (Sc), titanium (Ti), vanadium (V), chromium (Cr), manganese (Mn), yttrium (Y), zirconium (Zr), niobium (Nb), molybdenum (Mo), hafnium (Hf), tantalum (Ta) tungsten (W), rhenium (Re) and their isotopes. In an embodiment, multiple types of M cations (actinide and/or lanthanide and/or early transition metals) and/or multiple types of X anions (non-metals) can be built. In another embodiment, the superconducting material is selected from the group consisting of: ThIₙ (n=1.8 to 2.4), ThSₙ (n=0.8 to 1.4), TaCₙ (n=0.7 to 0.95), NbCₙ (n=0.75 to 0.80), TiCₙ (n=0.98 to 1.0), ZrCₙ (n=0.85 to 1.0), HfCₙ (n=0.8 to 1.0), and VCₙ (n=0.95 to 1.0).

An embodiment of this invention is exemplified by a couple of thorium (Th) salts. The disclosure focuses on these compounds, but this discussion is not intended to limit all embodiments of this disclosure to only the Th compounds.

The majority of the conductive thorium salts were synthesized at around the 1960s, such as: for ThI₂, Clark, R. J. and Corbett, J. D., “Preparation of Metallic Thorium Diiodide”, Inorg. Chem. 2, 460 (1963); for ThS, Eastman, E. D., et al., “Preparation and Properties of the Sulfides of Thorium and Uranium”, J. Am. Chem. Soc. 72, 4019 (1950), Tetenbaum, M. “Thermoelectric Properties of Uranium Monosulfide, Thorium Monosulfide, and US—ThS Solid Solutions”, J. Appl. Phys. 35, 2468 (1964), Shalek, P. D., “Preparation and Properties of Uranium and Thorium Monosulfides”, J. Am. Ceram. Soc. 46, 155 (1963), Samsonov, G. V. and Dubrovskaya, G. N., “THE PREPARATION OF CERTAIN SULFIDES OF THORIUM BY THE INTERACTION OF ThO₂ WITH HYDROGEN SULFIDE”, Atomnaya Energiya 15, 428 (1963), and Eastman, E. D. et al., “Preparation and Properties of the Oxide-Sulfides of Cerium, Zirconium, Thorium and Uranium”, J. Am. Chem. Soc. 73, 3896 (1950); for thorium carbides, nitrides and carbonitrides, Aronson, S. and Auskern, A. B., “Magnetic Susceptibility of Thorium Carbides, Nitrides, and Carbonitrides”, J. Chem. Phys. 48, 1760 (1968) and Auskern, A. B. and Aronson, S., “Electrical Properties of Thorium Carbonitrides”, J. Appl. Phys. 41, 227 (1970); and for thorium borides, Auskern, A. B. and Aronson, S., “Electrical Properties of Thorium Borides”, J. Chem. Phys. 49, 172 (1968), each of these is incorporated herein by reference. Besides their high electrically conductive feature under room temperature and atmospheric pressure, one of their inimitable properties is their diamagnetic behavior, also at ambient conditions, i.e., room temperature and pressure of one atmosphere. The related publications are: Clark, R. J. and Corbett, J. D., “Preparation of Metallic Thorium Diiodide”, Inorg. Chem. 2, 460 (1963), Eastman, E. D., et al., “Preparation and Properties of the Sulfides of Thorium and Uranium”, J. Am. Chem. Soc. 72, 4019 (1950), Auskern, A. B. and Aronson, S., “Electrical Properties of Thorium Borides”, J. Chem. Phys. 49, 172 (1968), and Auskern, A. B. and Aronson, S., “Electrical Properties of Thorium Borides”, J. Chem. Phys. 49, 172 (1968), each of which is incorporated herein by reference. This co-existence of electrically conductive and diamagnetic properties is usually unique to superconductors while normal conductors do not possess these characteristics. In addition, the term “ambient conditions” in this disclosure will be used to refer to the room temperature of 298 K and normal pressure of one atmosphere.

The aforementioned unique feature of the co-existence of both electrically conductive and diamagnetic properties under ambient conditions, i.e., the conditions that the compounds being characterized, indicate that this group of compounds should have reached their superconducting states at least at room temperature. In other words, these thorium compounds achieve their superconducting states at room temperature and under atmospheric pressure because of their unique property of co-existence of high electric conductivity and diamagnetism at ambient conditions.

In an embodiment, the dense superconducting material has a density of 0.00125 g/cm³ to 22 g/cm³, such as 0.014 g/cm³ to 20 g/cm³. In another embodiment, the density range of the compound MXₙ can be 0.05 g/cm³ to 20 g/cm³, 1 g/cm³ to 18 g/cm³ or 3 g/cm³ to 15 g/cm³. A typical way to measure the density of a sample is to get the weight of the sample and divide it by the measured sample volume. The volume of a sample can be determined by measuring its dimensions if it is in a regular shape or using the liquid displacement method. Another way to determine the sample's density is to use the sample's crystal structure. While it is obvious to know the volume of the crystal's lattice cell, the mass of the sample in the cell can be obtained by the atomic layout of the structure. The density would be hence deduced via the division of the mass by its volume in the cell. For example, the calculation using the crystal structures of ThS revealed the density of 9.624 g/cm³. Its crystallographic information used for the above calculation can be found from Eastman, E. D., et al., “Preparation and Properties of the Sulfides of Thorium and Uranium”, J. Am. Chem. Soc. 72, 4019 (1950), which is incorporated herein by reference.

Porosity in the superconducting material creates the potential to increase the field of application of the superconductors. Aerographene, a kind of aerogel made by carbon-carbon linkage, has a highly porous structure that can reduce its density to as low as 0.00016 g/cm³. This is a 99.993% of porosity compared to its basic building blocks of carbon. The related report of this work can be found online from: Farrell, D., “Graphene sponge becomes lightest material on earth”, vr-zone.com, retrieved Sep. 7 (2013), which is incorporated herein by reference. The process to create this kind of high porous structure can be applied in superconducting materials in this disclosure and thus to extend their application areas. In an embodiment, the superconducting material in this disclosure has a porosity of 0% to 27.9% and 28.1% to 99%, such as 0.001% to 25%, 0.1% to 20%, 50% to 98%, or 90% to 95% as determined by mercury intrusion porosimetry.

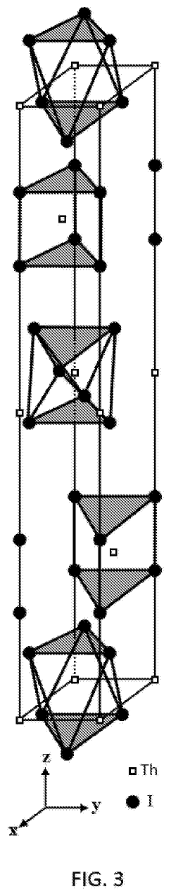

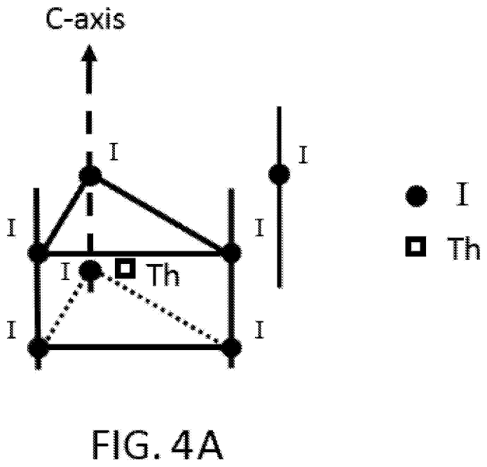

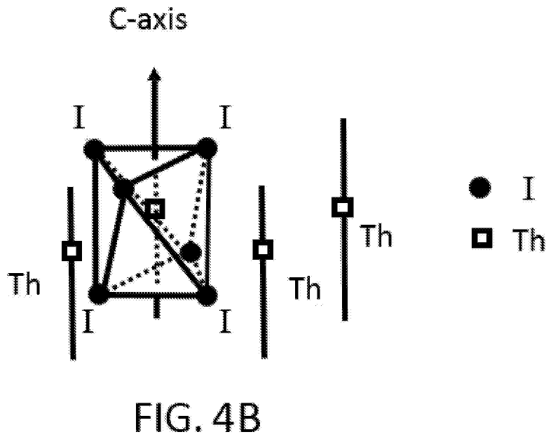

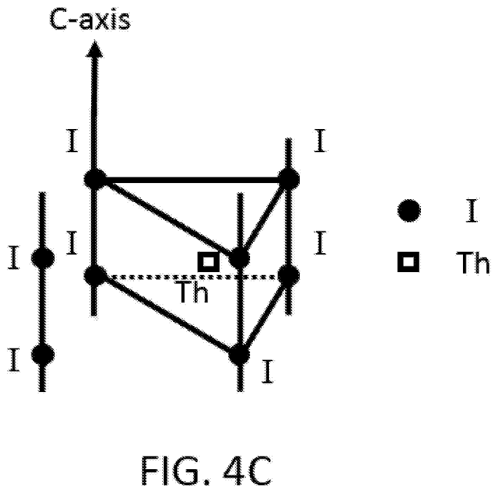

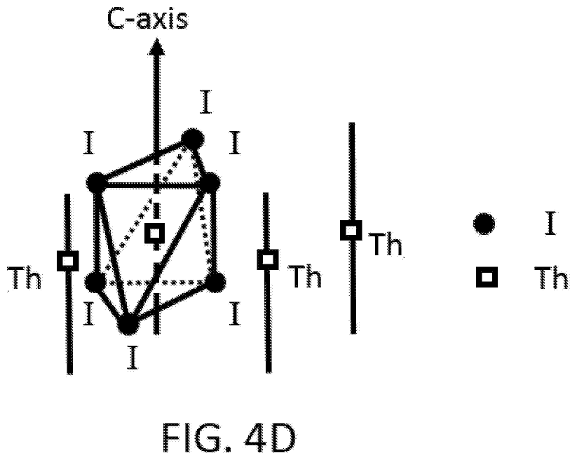

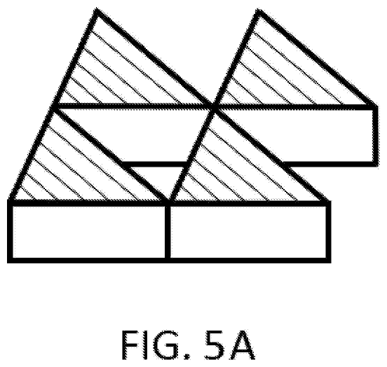

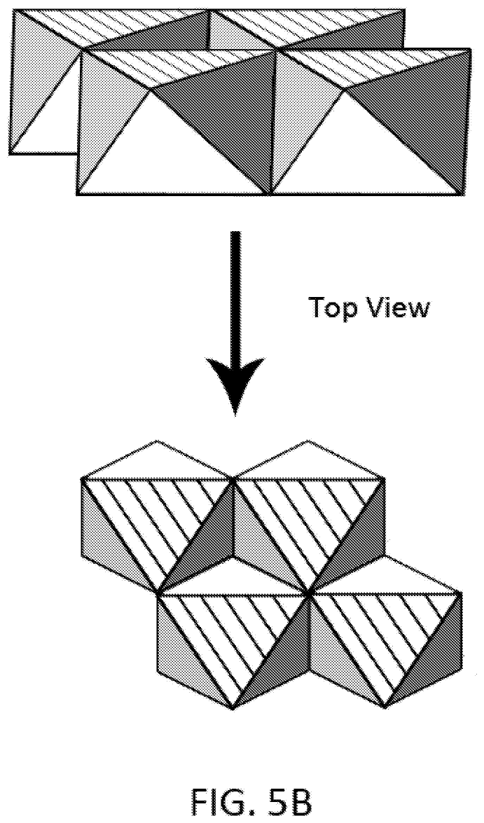

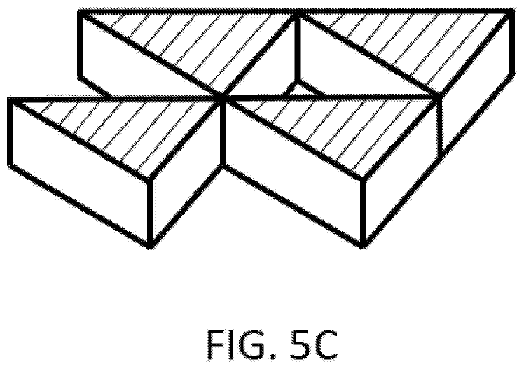

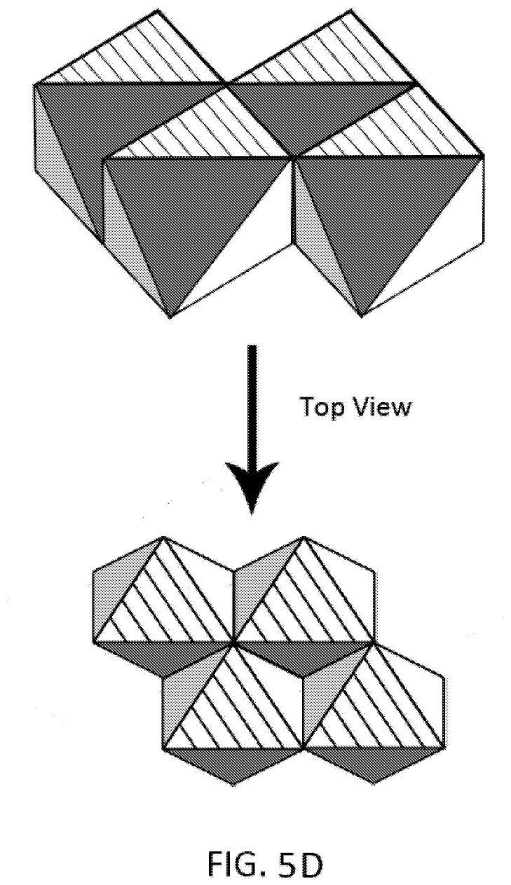

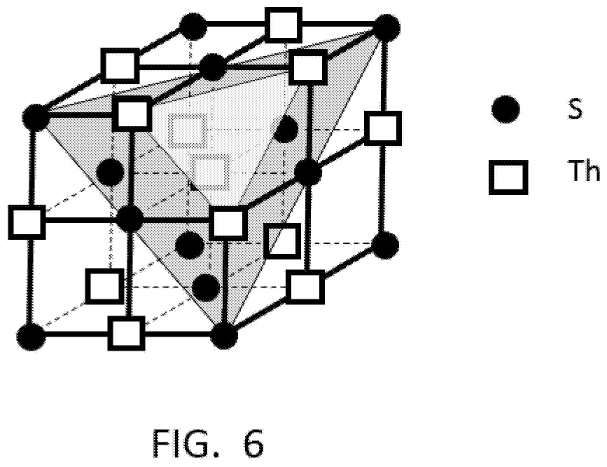

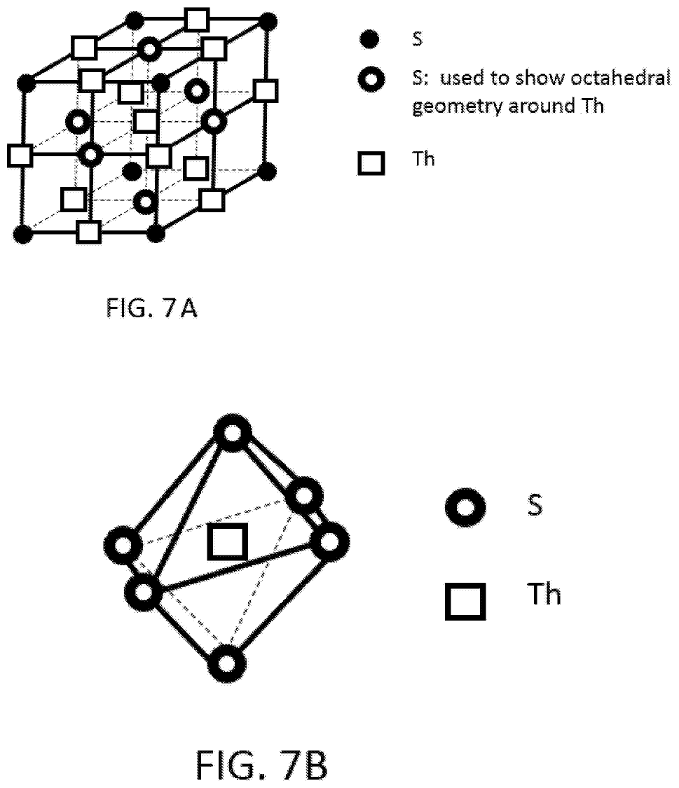

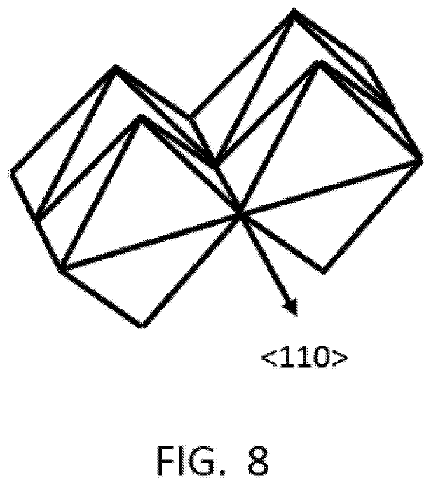

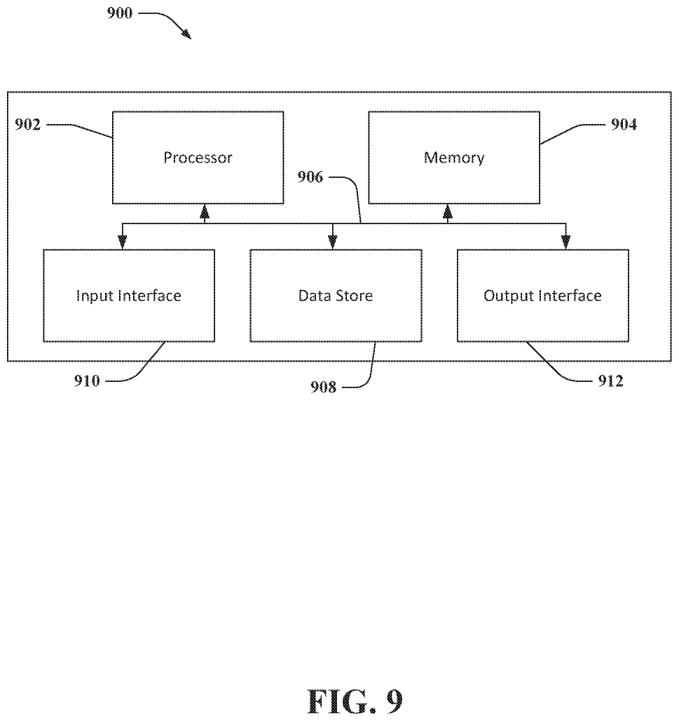

Investigations on the structural features of the thorium compounds were also performed. Their X-ray crystallographic results were analyzed, especially for thorium di-iodide (ThI₂) and thorium mono-sulfide (ThS). See: Guggenberger, L. J. and Jacobson, R. A., “The Crystal Structure of Thorium Diiodide”, Inorg. Chem. 7, 2257 (1968) for the details of single crystal X-ray crystallographic analysis of ThI₂; and Eastman, E. D., et al., “Preparation and Properties of the Sulfides of Thorium and Uranium”, J. Am. Chem. Soc. 72, 4019 (1950) and Didchenko, R. and Gortsema, F. P., “Magnetic and Electric Properties of Monosulfides and Mononitrides of Thorium and Uranium”, Inorg. Chem. 2, 1079 (1963) for the reports about the cubic NaCl typed structure of ThS, each of these publications is incorporated herein by reference. FIGS. 2-8 disclose details of the analyses of these references. FIGS. 2 and 3 are re-plotted from Guggenberger. FIG. 4A to FIG. 5D are based on a replotting of the information in Guggenberger. FIG. 6 to FIG. 8 are plotted based on information in Eastman and Didchenko.

ThI₂ crystallizes in space group P6₃/mmc in hexagonal lattice with a-axis of 0.397 nm and an exceptional long c-axis of 3.175 nm. The reason for the long c-axis is because each Th cation is surrounded by 6 I anions in two geometries, i.e., trigonal-antiprismatic (anti-Pris) and trigonal-prismatic (Pris) arrangements. (See FIGS. 2A and 2B.) Each hexagonal cell consists of four layers of them along c-axis packed in an alternating manner, i.e., anti-Pris/Pris/anti-Pris/Pris. (See FIG. 3.) Each individual trigonal-prismatic or trigonal-antiprismatic of their pairs in a crystallographic unit cell is located at different cell positions and different orientations on their (0001) planes, i.e., atoms of trigonal-prismatic (or trigonal-antiprismatic) having different x and y values relative to another trigonal-prismatic (or trigonal-antiprismatic) of their pairs in the lattice. We re-plotted its unit cell and its individual [ThI₆] structures layer by layer, and we also expanded the plotting of each layer into 4 unit cells. (See FIGS. 4A to 5D.) The 4-cell plotting exhibited the planar structure through joining the common edges of either trigonal-antiprismatic or trigonal-prismatic [ThI₆] structural units to construct the two dimensional layered linkage running on the planes parallel to the c-axis. The similar structural feature of this layered edge sharing connections has also been observed in the crystallographic packing style of other superconductors. (Refer to: Mankowsky, R., et al., “Nonlinear lattice dynamics as a basis for enhanced superconductivity in YBa₂Cu₃O_{6.5}”, Nature 516, 71-73 (2014), Hu, W., et al., “Optically enhanced coherent transport in YBa₂Cu₃O_{6.5} by ultrafast redistribution of interlayer coupling”, Nature Mater. 13, 705-711 (2014), Kaiser, S., et al., “Optically induced coherent transport far above Tc in underdoped YBa₂Cu₃O_{6+δ}”, Phys. Rev. B 89, 184516 (2014), Bednorz, J. G. and Muller, K. A., “Possible High Tc Superconductivity in the Ba—La—Cu—O System”, Z. Phys. B 64, 189 (1986), and U.S. Pat. No. 8,435,473 B2, each of which is incorporated herein by reference.) This further indicates that ThI₂ meets the structural criterion for being a superconducting material.

ThS has similar electromagnetic properties as ThI₂ but its crystal structure is cubic (See FIGS. 6 to 8), which is the same as the packing of sodium chloride (NaCl), with a=0.568 nm. Its crystallographic structure also revealed the two-dimensional layered linkage along <110> directions with edge-sharing characters assembled by the structural units of the [ThS₆] octahedra. The character of this crystallographic layered packing for the ThS compound, again, qualifies the structural demand as a superconductor.

Instead of iodide and sulfide, the co-existence of electric conductivity and diamagnetism associated with actinide compounds, especially for thorium compounds, at relatively high temperature, i.e., 151 K or above, may also be found for their carbide, nitride, boride, etc., as well as their combinations, such as carbonitride. These compounds can also become the candidates for the high temperature superconducting materials of this invention.

ThC_{0.78}N_{0.22} is reported being a superconductor but its Tc is too low at about 5.8 K as explored in Shein, I. R., et al., “Electronic structure and stability of thorium carbonitrides”, Phys. Stat. Sol. (b) 244, 3198 (2007), which is incorporated herein by reference. This compound does not have the property of co-existence of both electric conductivity and diamagnetism at 151 K or higher. Therefore, this compound is excluded from the superconductors disclosed herein, even though its molecular formula falls into the MXₙ compositions as remarked in this disclosure. In other words, only these compounds that fit the formula of MXₙ described hereinbefore and have their Tc of 151 K or higher belong to the superconductors disclosed herein. Moreover, compound ThC_{0.78}N_{0.22} matches the formula of MXₙ in a way that M=Th, X=C_{0.78}N_{0.22}, viz, the binary anion, and n=0.78+0.22=1.

Another study about the superconducting property of a thorium salt is ThC_{0.6}N_{0.4} as presented in Maurice, V., et al., “Low temperature specific heat of rocksalt thorium compounds”, J. De Physique C4-140 (1979), incorporated herein by reference. The authors described a slow superconducting transition of this compound at Tc of 3.8 to 4.2 K. Upon cooling toward its Tc, its electric resistivity drops dramatically from 4.2 K while its magnetic property turns to diamagnetism at 3.8 K, a clear sign exhibiting the completely transiting into the superconducting state of the compounds. Again, while the Tc of this compound is too low to be ruled out from the candidate of this invention, this reference indicates how those of skill in the art have used the diamagnetism property to determine Tc.

In an embodiment, the superconducting material is a solid at room temperature (298 K) and atmospheric pressure, i.e., 1 atm. In an embodiment, the superconducting state of the material is also stable at ambient condition, in that it does not require any externally applied energy (such as, for example, elevated pressure or radiation/electric field) to maintain its superconducting property. In an embodiment, the superconducting material is in the form selected from the group consisting of a single crystal, polycrystalline or amorphous, bulk, thin film/coating, powder, or single molecular layer. In an embodiment, it is in the form of a wire or a trace or other types of shapes. In an embodiment, the superconducting material is at least 98% pure by weight, such as 98.5% to 99.9% pure. In another embodiment, the superconducting material is at least 95% by weight pure, such as 96% to 99% pure.

A method of utilizing the materials disclosed herein comprises conducting electricity through the materials with no resistance, or at very low resistivity, such as, one fiftieth of copper's resistivity or the upper limit of the apparatus's sensitivity at 33.6 nΩ·cm or lower as defined in U.S. Pat. No. 8,404,620 B2 and Wu, M. K, et al., “Superconductivity at 93 K in a New Mixed-Phase Y—Ba—Cu—O Compound system at Ambient Pressure”, Phys. Rev. Lett. 58 (9) 908 (1987), each of which is incorporated herein by reference. Furthermore, the electricity is conducted in an electronic device to efficiently provide power to or in the device. The electric current may be alternating or direct current.

In an embodiment, a current, which may be a super current, may have a current density, other than from 2465 A/m² to 4931 A/m² and/or where the sample size is other than 7.8 mm×2.6 mm×1.5 mm. The high end of the critical current density may surpass 1,000,000 kA/m² as described in U.S. Pat. No. 6,586,370 B1, which is incorporated herein by reference. In an embodiment, the critical current density passing through the superconducting material is at least 5,000,000 kA/m². In an embodiment, the current density is 0.001 A/m² to 2460 A/m² and/or 3000 A/m² to 5,000,000 kA/m²; such as, for example 0.01 A/m² to 2000 A/m², or 0.1 A/m² to 100 A/m²; and/or 10 kA/m² to 1000 kA/m², or 20,000 kA/m² to 2,000,000 kA/m². In an embodiment, the electrical current passing through the superconducting material is other than from 1 pA to 100 mA, such as 10 pA to 49 mA and/or 101 mA to 10 kA, for example, 5 mA to 40 mA, 10 mA to 35 mA, and/or 150 mA to 5 kA, or 1 A to 1 kA. The superconducting material may, for example, have a volume of 1 nm³ to 900 μm³ and/or 0.001 mm³ to 30 mm³ and/or 31 mm³ to 900 m³, such as, for example, 0.01 mm³ to 25 mm³, or 0.1 mm³ to 20 mm³; and/or 35 mm³ to 10 m³, or 40 mm³ to 1 m³.

In an embodiment, the superconductors in this disclosure have the critical magnetic field of 5 tesla (T) or over as stated in U.S. Pat. No. 6,586,370 B1, which is incorporated herein by reference. In an embodiment, the critical magnetic field is hoped to be 21 T or even 100 T. In an embodiment, the critical magnetic field of the superconductor in this disclosure could even be as high as 500 T.

Most type II high temperature superconductors are layered structures and hence highly anisotropic as presented in U.S. Pat. No. 6,586,370 B1 and Mourachkine, A., “Room-Temperature Superconductivity”, Cambridge International Science Publishing (2004), each of which is incorporated herein by reference. This means these type II superconductors only allow the super-currents to flow in some directions as confined by the intrinsic layered structural feature. In an embodiment, the superconducting material of this disclosure has an isotropic property, such that the super-current flow through this compound is not necessarily confined in the two dimensional layers as shown in the typical type II superconductors. This makes the isotropic type of superconductors more favorable than most of the layered type II superconductors for a number of applications, especially for the applications requiring high current density or where the current needs to flow in all three dimensions or directions of an object. In an embodiment, ThS may have isotropic property of conducting electric current as each thorium cation on its conductive layer share the group layers of {111}) crystallographic family planes. This means the Th cations belong to all the planes that define different directions associated to the planes of {111}) family, such as (1 1 1), (1 −1 1), (1 −1 −1), (−1 1 1), etc. This makes the thorium cations 3D like networking structural feature.

In another embodiment, a method utilizing the materials disclosed herein comprises utilizing the materials disclosed herein at a temperature of at least 151 K to provide a magnetic field. The magnetic field is used in a device, such as an MRI, to efficiently provide magnetic or magnetically induced effects in the device. Certain devices or systems may comprise both magnetic and electronic interactions.

The materials and methods disclosed herein may be used in various electronic articles of manufacture and systems, generally including electronic devices and/or devices that include a magnetic component.

Even though, there are limitless applications associated with utilizing the superconducting properties of the materials, only several specific examples of such articles of manufacture and systems incorporating them are included:
1. Superconducting magnets, in which the superconducting materials need not be cooled to cryogenic temperatures, thereby enabling significant improvements in energy efficiency and miniaturization of systems as well as cost economy after eliminating the cryogenic components.
2. Magnetic sensors, and devices that include the same, such as a superconducting quantum interference device (SQUID). The application of room-temperature superconductor can boost the performance of this magnetometer without having a cryogenic component.
3. A single flux quantum device (SFQ), such as used as logical circuits for high speed, low power consumption circuits.
4. Energy storage devices, for example, friction-free flywheel-type electricity storage systems.
5. Devices utilizing magnetic flux pinning, which can create very high magnetic fields that can be used, for example, in water cleaning systems that may be 100 times more efficient than current devices. Such devices include a permanent magnet magnetically coupled to a superconductor.
6. Magnetically levitated transportation systems (MEGLEV), such as the superfast train, which recorded the highest speed of 603 km/h, and floats above its permanent magnetic guideway through electromagnetic suspension with powerful superconducting electromagnets on the train. Without using refrigerant system, the application of the room temperature superconducting materials would not only save more spaces on the train but also can enable MEGLEV to be more energy efficient.
7. Continuous casting systems in steel mills.
8. High-power motors for ship propulsion systems.
9. Superconducting magnetic energy storage (SMES) system.
10. Other sensor applications such as physical (e.g., temperature, pressure), chemical, biological, and biomedical (for scientific and defense) sensors.
11. Cables or wires for no energy loss transportation of electricity.
12. For application of integrated circuit, to avoid the generation of excess heat.
13. Processor chip or circuits using superconducting lines to interconnect its different components. Using the superconducting material in such a manner would intensely speed up the rate of processing data and give tremendous enhancement of performance on circuits in general.
14. Multiple magnet system for magnetic ore separation.
15. Nuclear magnetic resonance (NMR) and magnetic resonance imaging (MRI).
   The high magnetic field would be generated without cooling down to low temperature when the room temperature superconductors are employed.
16. Superconducting quadrupoles for a beam line of decaying particles.
17. Electrode materials or composite of electrode materials to enhance conductivity of other materials.
18. Superconducting toys.
19. Compact superconducting motors. These could replace noisy, polluting engines.
20. Memory/storage device such as superconductor ballistic Random Access Memories (RAMs) or persistent current storage device.
21. Small sized electrical generator and transformer. These could be made exceptionally more efficient.
22. Large distance power transmission (ρ=0).
23. Switching devices could be designed in a way to monitor the temperature change based on superconductor's Tc. Upon approaching the Tc, the superconductor's property would dramatically change and hence to trigger the switch after sensing the change.
24. Superconducting solenoids.
25. Magneto, used in energy conversion or power generation systems by magnetic induction, such as used in thermal, hydroelectric and turbine driven renewable power plants.
26. Josephson devices, such as magnetic sensors, gradiometers, oscilloscopes, decoders, analogue to digital converters, oscillators, microwave amplifiers.
27. Passive RF and microwave filter for wide-band communications and radars. Very low noise and much higher selectivity and efficiency than conventional filters.
28. Quantum computing circuits.
29. Superconducting tunnel junction (STJ) made by joining two pieces of superconductors with a very thin layer of insulator is the most sensitive type of heterodyne receivers in the frequency range of 100 GHz to 1000 GHz.
30. Nuclear fusion energy generating apparatuses.
31. The application of room temperature superconductor in building the magnet for a Hall Effect measurement system would substantially increase the efficiency and reduced the weight and size of the system.
32. The application of room temperature superconductor in building the magnet for a Vibrating Sample Magnetometer (VSM) for measuring sample's magnetic properties such as magnetic moment and coercivity.
33. The application of room temperature superconductor in preparing a high porosity material, such as aerogel, which may be employed in building electric circuitry or wires that could have some benefit like enabling better heat dissipation.
34. Mass spectrometry. The room temperature superconductor can be utilized to generate electromagnetic field for mass spectrometer that separates the positive rays according to the charge to mass ratio for chemical analysis.
35. Terahertz technology.

Application of terahertz technology, includes, for example, using Josephson junctions as the source of terahertz radiation. The intrinsic layered structure of type-II superconductor with alternating conducting and insulating layers make the density of Josephson junctions extremely high and thus, can serve as a very efficient terahertz emitter at high temperature. Exemplary details of such a method and system can be found in Nakade, K., et al., “Applications using high-Tc superconducting terahertz emitters”, Sci. Rep. 17, 1 (2016), which is incorporated herein by reference. The method of use of the materials could be more specifically used, for example, to operate the devices disclosed above.

In any of the articles of manufacture mentioned above, at least a portion of the electrically conducting or magnetic material in the article of manufacture is the superconducting material.

In a particular embodiment, an exemplary computing device 900 that can be used in accordance with the superconducting materials disclosed herein is illustrated. At least a portion of the electrical connections between the components or within the components comprise the superconducting material. The computing device 900 includes data storage 908 that is accessible by the processor 902 by way of a system bus 906. The data storage 908 may include executable instructions to operate the processor 902 and other components. The computing device 900 also includes an input interface 910 that allows external devices to communicate with the computing device 900. For instance, the input interface 910 may be used to receive instructions from an external computer device, from a user, etc. The computing device 900 also includes an output interface 912 that interfaces the computing device 900 with one or more external devices. For example, the computing device 900 may display text, images, etc. by way of the output interface 912.

The data storage is a computer-readable storage media, and can be any available storage media that can be accessed by a computer. By way of example, and not limitation, such computer-readable storage media can comprise RAM, ROM, EEPROM, or magnetic disk storage or other magnetic storage devices, or any other medium that can be used to carry or store desired program code in the form of instructions or data structures and that can be accessed by a computer. Combinations of the above should also be included within the scope of computer-readable media.

Alternatively, or in addition, the superconducting material described herein can be utilized in hardware logic components. For example, and without limitation, illustrative types of hardware logic components that can be used include Field-programmable Gate Arrays (FPGAs), Program-specific Integrated Circuits (ASICs), Program-specific Standard Products (ASSPs), System-on-a-chip systems (SOCs), and Complex Programmable Logic Devices (CPLDs).

Routes of syntheses of embodiments of the high temperature superconductors are provided below. The previous synthetic work of the conductive Th compounds that took place around the 1960s ended up with about 5% impurities by weight as illustrated in Eastman, E. D., et al., “Preparation and Properties of the Sulfides of Thorium and Uranium”, J. Am. Chem. Soc. 72, 4019 (1950) and Shalek, P. D., “Preparation and Properties of Uranium and Thorium Monosulfides”, J. Am. Ceram. Soc. 46, 155 (1963), which are incorporated herein by reference. The majority of the impurities were confirmed non-stoichiometric species and Th oxides. Present day synthetic pathways may improve the purity with the use of more sophisticated facilities and procedures now known to those of skill in the art. The reasons for these changes are for controlling the stoichiometry of the syntheses as well as avoiding the oxidation and/or contamination by oxygen and water under the high synthetic temperatures, i.e., up to 2200° C., with or without employing vacuum or inert atmosphere techniques in order to obtain the pure compounds. Even though, the high purity of the materials in this disclosure is desired, the low purity of the same materials may still possess superconducting properties and may still be able to be utilized in some of the applications. Consequently, not all embodiments of this disclosure are to exclude the impure compounds. The examples of synthetic routes, hereinafter, are only used to exemplify the ideal situation that the superconducting materials can be made stoichiometrically without oxygen or water oxidation.

High temperature solid state reaction can be utilized to synthesize the compounds. Thorium, as one of the most studied elements in the actinide group, will be described here while ThS will be discussed.

Albeit many methods of synthesizing thorium sulfide were reported, only two major preparative routes for ThS were utilized here to show the basic ways on making this compound, i.e., two-step synthesis and one-step method.

### Prophetic Example 1: Two-Step Route

The two-step synthetic route requires the first preparation of thorium di-sulfide (ThS₂) as the starting material for the second step.

ThS₂ can be made by reacting thorium metal dioxide (ThO₂) with excess amount of hydrogen sulfide (H₂S) in present of carbon at around 1200-1500° C. The duration of the reaction has not been reported but the chemical reaction was claimed to be very fast.

ThS can thus be synthesized by mixing the stoichiometric amount of ThS₂ with thorium metal hydride and heated to 400-600° C. The reactant can then be homogenized under 2000-2200° C. in reduced pressure (˜10⁻⁵ Torr). More information on these techniques can be found in Eastman, E. D., et al., “Preparation and Properties of the Sulfides of Thorium and Uranium”, J. Am. Chem. Soc. 72, 4019 (1950) and Tetenbaum, M. “Thermoelectric Properties of Uranium Monosulfide, Thorium Monosulfide, and US-ThS Solid Solutions”, J. Appl. Phys. 35, 2468 (1964), each of which is incorporated herein by reference.

### Prophetic Example 2: One-Step Route

Heating the mixture of thorium metal hydride and proper amount of H₂S to about 2000° C. under reduced pressure (˜10⁻⁵ Torr) could produce ThS. More information on this techniques can be found in Tetenbaum, M., “Thermoelectric Properties of Uranium Monosulfide, Thorium Monosulfide, and US—ThS Solid Solutions”, J. Appl. Phys. 35, 2468 (1964), which is incorporated herein by reference. This one-step route is relatively simple but the control of the stoichiometry of the reactants to produce the pure ThS may be challenging.

### Prophetic Example 3: Preparation of Thorium Hydride

The reaction to form thorium hydride (ThH₂) proceeds relatively easy depending on the temperature. See Eastman, E. D., et al., “Preparation and Properties of the Sulfides of Thorium and Uranium”, J. Am. Chem. Soc. 72, 4019 (1950), which is incorporated herein by reference. For converting 300 grams of thorium metal into thorium hydride, the duration is about 10 hours at 300° C. But the time duration can be reduced to only a few minutes if the temperature is increased to 400-500° C. initially and then decreased to 300° C. after the reaction starts.

### Prophetic Example 4: Experiments to Test the Superconductivity of Thorium Monosulfide

There are a number of methods to test the property of superconductivity of a sample. Among them, the measurement of resistivity against temperature and Meissner effect are the most used. However, the methods similar to that discussed in this disclosure are also popular. See for example, the methods disclosed in Maurice, V., et al., “Low temperature specific heat of rocksalt thorium compounds”, J. De Physique C4-140 (1979), Tanaka, S., “High-Temperature Superconductivity: History and Outlook”, JSAP international 4, 17 (2001), U.S. Patent Application Publication, 2011/0002832 A1, and Wu, M. K, et al., “Superconductivity at 93 K in a New Mixed-Phase Y—Ba—Cu—O Compound system at Ambient Pressure”, Phys. Rev. Lett. 58 (9) 908 (1987), each of which is incorporated herein by reference. The method of determining diamagnetism used in Tanaka, can be used to determine the diamagnetism mentioned in the claims. The resistivity and diamagnetic properties were employed to determine the compound's Tc in these references. It is noticed that the methods used in the literatures are essentially the same as described in this disclosure, i.e., the co-existence of conductivity and diamagnetism of the samples reached when the temperatures of samples are below their Tc. For the exemplary material of this disclosure, it can be tested even easier than the compounds in the aforementioned publications because some of the Tc's of the compounds disclosed herein, such as ThI₂, ThS, etc., should be at 298 K or above and the employment of Meissner effect will no longer require cooling down the temperature and the sample can just be observed to float above a magnet at ambient condition.

Another simple experiment is to utilize the Josephson Effect by building a Josephson junction, i.e., sandwiching a thin insulator layer by two superconducting pieces as two electrodes. When scanning voltage and recording the current across these two electrodes, it will be found that there will be non-zero current, i.e., the Josephson current (I_{c}), at zero voltage due to the tunneling of Cooper pairs if the experimental temperature is lower than the sample's Tc. The details of the experiment can be found in Mourachkine, A., “Room-Temperature Superconductivity”, Cambridge International Science Publishing (2004), which is herein incorporated by reference.

Normal conductors would neither show the Meissner effect nor the Josephson tunneling effect.

### Prophetic Example 5: Determination of Superconducting Transition Temperature

The Tc of the superconductors in this disclosure and as recited in the claims can be determined by variable temperature measurements of sample's resistivity as in Bednorz, J. G. and Muller, K. A., “Possible High Tc Superconductivity in the Ba—La—Cu—O System”, Z. Phys. B 64, 189 (1986), Maurice, V., et al., “Low temperature specific heat of rocksalt thorium compounds”, J. De Physique C4-140 (1979) and Wu, M. K, et al., “Superconductivity at 93 K in a New Mixed-Phase Y—Ba—Cu—O Compound system at Ambient Pressure”, Phys. Rev. Lett. 58 (9) 908 (1987), which are incorporated herein by reference. Since a number of the samples, such as ThI₂ and ThS, have Tc of 298 K or higher, the measurement of the sample's Tc may be carried out by increasing the temperature from below their Tc such as 298 K or slightly lower under constant normal pressure of one atmosphere. The Tc can be obtained to the value at the temperature point right after the completion of the sudden raise in their resistivity. The Tc should be verified by performing the cooling down experiment, such as from above the sample's Tc, and gradually decreasing the temperature. The Tc value can be confirmed when the resistivity experiences a sudden drop. This experiment normally couples with the variable temperature measurement of the sample's magnetic susceptibility as in Dai, P., et al., “Synthesis and neutron powder diffraction study of the superconductor HgBa₂Ca₂Cu₃O_{8+δ} by Tl substitution”, Physica C243, 201 (1995), Maurice, V., et al., “Low temperature specific heat of rocksalt thorium compounds”, J. De Physique C4-140 (1979) and Wu, M. K, et al., “Superconductivity at 93 K in a New Mixed-Phase Y—Ba—Cu—O Compound system at Ambient Pressure”, Phys. Rev. Lett. 58 (9) 908 (1987), which are incorporated herein by reference. The temperature at the changes from or to the diamagnetic property of the sample, with the experiments of warming up or cooling down respectively, corresponds to the sample's Tc.

### Prophetic Example 6: Superconducting Computing

The success of obtaining room temperature superconducting materials would dramatically change the computing world as the more energy efficient and less heat generating logic circuits, including zero-resistance wires and ultra-fast Josephson junction switches, could be available without the need of cryogenic components. Because of the much-reduced heat dissipation from the circuitry, three-dimensional stacking of components becomes possible and therefore, substantial improvements in size reduction can be attained while enhancing operating speed.

What has been described above includes examples of one or more embodiments. It is, of course, not possible to describe every conceivable modification and alteration of the above devices or methodologies for purposes of describing the aforementioned aspects, but one of ordinary skill in the art can recognize that many further modifications and permutations of various aspects are possible. Accordingly, the described aspects are intended to embrace all such alterations, modifications, and variations that fall within the spirit and scope of the appended claims. Furthermore, to the extent that the term “includes” is used in either the details description or the claims, such term is intended to be inclusive in a manner similar to the term “comprising” as “comprising” is interpreted when employed as a transitional word in a claim. The term “consisting essentially” as used herein means the specified materials or steps and those that do not materially affect the basic and novel characteristics of the material or method. All percentages and averages are by weight unless the context indicates otherwise. If not specified above, the properties mentioned herein may be determined by applicable ASTM standards, or if an ASTM standard does not exist for the property, the most commonly used standard known by those of skill in the art may be used. The articles “a,” “an,” and “the,” should be interpreted to mean “one or more” unless the context indicates the contrary.

It is claimed:

1. A method for conducting electricity with no resistance, the method comprising:
generating an electrical current;
passing the electrical current other than from 50 mA to 100 mA and the sample size other than 7.8 mm×2.6 mm×1.5 mm through a superconducting material defined by the formula MXₙ, or salts thereof, at atmospheric pressure;
wherein M is at least one element selected from the group consisting of: thorium (Th), protactinium (Pa), uranium (U), Neptunium (Np), plutonium (Pu), americium (Am), curium (Cm), berkelium (Bk), californium (Cf), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), scandium (Sc), titanium (Ti), vanadium (V), chromium (Cr), manganese (Mn), yttrium (Y), zirconium (Zr), niobium (Nb), molybdenum (Mo), hafnium (Hf), tantalum (Ta) tungsten (W), rhenium (Re) and their isotopes;
X is at least one element selected from the group consisting of: fluorine (F), chlorine (Cl), bromine (Br), iodine (I), oxygen (O), sulfur (S), selenium (Se), tellurium (Te), nitrogen (N), phosphorus (P), arsenic (As), antimony (Sb), carbon (C), silicon (Si), germanium (Ge), boron (B) and their isotopes;
n is 0.05 to 20;
and the superconducting material has a Tc of 151 K or greater under normal atmospheric pressure of 1 atm.

2. The method of claim 1, wherein the superconducting material is diamagnetic at 151 K or higher and at 1 atm pressure.

3. The method of claim 1, wherein the superconducting material is a solid at its Tc at 1 atm pressure.

4. The method of claim 1, wherein the Tc of the superconducting material is 273 K to 550 K.

5. The method of claim 1, wherein the superconducting material is selected from the group consisting of: ThIₙ (n=1.8 to 2.4), ThSₙ (n=0.8 to 1.4), TaCₙ (n=0.7 to 0.95), NbCₙ (n=0.75 to 0.80), TiCₙ (n=0.98 to 1.0), ZrCₙ (n=0.85 to 1.0), HfCₙ (n=0.8 to 1.0) and VCₙ (n=0.95 to 1.0).

6. The method of claim 1, wherein the superconducting material is in the form selected from the group consisting of a single crystal, polycrystalline or amorphous, bulk, thin film/coating, powder, or single molecular layer.

7. The method of claim 1, wherein the superconducting material is in the form of a wire or trace.

8. The method of claim 1, wherein the superconducting material has a layered molecular configuration connected through repeating structural units or coordination polyhedrons with M in a center of the polyhedrons.

9. The method of claim 1, wherein no external energy is applied to maintain a superconducting state of the superconducting material.

10. The method of claim 1, wherein the superconducting material is at least 95% purity by weight.

11. The method of claim 1, wherein the electric current is alternating current.

12. The method of claim 1, wherein the superconducting material comprises an actinide series metal that has a low level of radioactivity, ranging from a half-life of 300 years to 15 billion years with a least penetrable alpha-decay process.

13. An article of manufacture comprising:
an electrical input electrically coupled to a superconducting material;
the superconducting material electrically or magnetically coupled to an electronic device or magnetic device;
wherein the superconducting material is defined by the formula MXₙ, or salts thereof, and M is at least one element selected from the group consisting of: thorium (Th), protactinium (Pa), uranium (U), Neptunium (Np), plutonium (Pu), americium (Am), curium (Cm), berkelium (Bk), californium (Cf), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), scandium (Sc), titanium (Ti), vanadium (V), chromium (Cr), manganese (Mn), yttrium (Y), zirconium (Zr), niobium (Nb), molybdenum (Mo), hafnium (Hf), tantalum (Ta) tungsten (W), rhenium (Re) and their isotopes;
X is at least one element selected from the group consisting of: fluorine (F), chlorine (Cl), bromine (Br), iodine (I), oxygen (O), sulfur (S), selenium (Se), tellurium (Te), nitrogen (N), phosphorus (P), arsenic (As), antimony (Sb), carbon (C), silicon (Si), germanium (Ge), boron (B) and their isotopes;
n is 0.05 to 20;
and the superconducting material has a Tc of 151 K or greater at atmospheric pressure.

14. The article of manufacture of claim 13, wherein the article of manufacture is selected from the group consisting of: a superconducting magnet in a magnetic device; a magnetic sensor; a computing device; a computer-readable storage media; a single flux quantum device, an energy storage device; a device utilizing magnetic flux pinning; a magnetically levitated transportation system; a continuous casting system; a ship propulsion system; a superconducting magnetic energy storage (SMES) system; temperature, pressure, chemical, biological or biomedical sensors; a cable or a wire; an integrated circuit; multiple magnet systems for magnetic ore separation; a nuclear magnetic resonance (NMR) device, a magnetic resonance imaging (MRI) device; a superconducting quadrupole for a beam line of decaying particle; an electrode material or a composite of electrode material to enhance the conductivity of other materials; a superconducting toy; a compact superconducting motor; a memory/storage device utilizing persistent current; an electrical generator or transformer; an electrical or magnetic switching device; a superconducting solenoid; a magneto hydrodynamic power generator; a plasma containment system; Josephson devices; passive RF or microwave filters for wide-band communications and radar; quantum computing circuits; a superconducting tunnel junction; or a nuclear fusion energy generating apparatus; a superconducting-based Hall effect measurement system; a superconductor based vibrating sample magnetometer; a superconductor based mass spectrometer; a superconducting terahertz emitter; a computer using a superconducting logic circuit; a circuitry or wire made of high porosity or aerogel material
wherein at least a portion of electrically conducting or magnetic material in the article of manufacture is the superconducting material.

15. The article of manufacture of claim 14, wherein the article of manufacture is selected from the group consisting of: a computing device; an integrated circuit, a computer processor, or a quantum computing circuit.

16. The article of manufacture of claim 13, wherein the superconducting material is at least 95% purity by weight.

17. The article of manufacture of claim 13, wherein the superconducting material is selected from the group consisting of: ThIₙ (n=1.8 to 2.4), ThSₙ (n=0.8 to 1.4), TaCₙ (n=0.7 to 0.95), NbCₙ (n=0.75 to 0.80), TiCₙ (n=0.98 to 1.0), ZrCₙ (n=0.85 to 1.0), HfCₙ (n=0.8 to 1.0), and VCₙ (n=0.95 to 1.0).

18. The article of manufacture of claim 13, wherein the superconducting material has very low resistivity when measured at 298 K and 1 atm, wherein the very low resistivity is one fiftieth of copper's resistivity at 33.6 nΩ·cm or lower.

19. A method for conducting electricity with no resistance, the method comprising:
generating an electrical current;
passing the electrical current other than 50 mA to 100 mA and the sample size other than 7.8 mm×2.6 mm×1.5 mm, through a superconducting material at atmospheric pressure;
wherein the superconducting material is defined by formula MXₙ, wherein, M is thorium (Th) and X is sulfur (S), iodine (I), nitrogen (N), carbon (C), boron (B) and their isotopes; wherein,
n is 0.05 to 20;
and the superconducting material has a Tc of 151 K or greater at atmospheric pressure.

20. The method of claim 19, wherein, the superconducting material is ThSₙ, wherein, n is 0.8 to 1.4, and the superconducting material has conductive layers, wherein the superconducting material has an isotropic property, wherein each thorium cation on the conductive layers shares the group layers of {111}) crystallographic family planes, wherein all the Th cations form 3D networking interactions amongst themselves.
